(19) United States
(12) Patent Application Publication
(10) Pub. No.: US 2007/0205416 A1
(43) Pub. Date: Sep. 6, 2007

(54) LIGHT EMITTING ELEMENT, LIGHT EMITTING DEVICE AND ELECTRONIC DEVICE

(75) Inventors: Junichiro SAKATA, Atsugi (JP); Kohei YOKOYAMA, Ayase (JP); Yoshiaki YAMAMOTO, Atsugi (JP); Takahiro KAWAKAMI, Isehara (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/679,397

(22) Filed: Feb. 27, 2007

(30) Foreign Application Priority Data
Mar. 3, 2006 (JP) 2006-058580

(51) Int. Cl. H01L 33/00

(52) U.S. Cl. 257/79

(57) ABSTRACT

A light emitting element that can be driven at a low voltage is provided. Further, a light emitting device and an electronic device with reduced power consumption are provided. A light emitting element is provided that includes a substrate 100, and a first electrode 101, a first insulating layer 102, a light emitting layer 103, a second insulating layer 104, and a second electrode 105, which are over the substrate 100. The light emitting layer 103 includes a compound ABC₂, referred to as a ‘chalcopyrite’ (wherein A is Cu or Ag, B is Al, Ga, or In, and C is S, Se, or Te). By employing such a structure, a light emitting element that can be driven at a low voltage can be provided.

### TECHNICAL FIELD

The present invention relates to light emitting materials. Further, the present invention relates to light emitting devices that utilize electroluminescence. Moreover, the present invention relates to light emitting devices and electronic devices that have a light emitting element.

### BACKGROUND ART

In recent years, concerning display devices in televisions, portable telephones, digital cameras and the like, there has been a demand for planar, slim display devices. As display devices which meet this demand, display devices which employ tight emitting elements of a self-luminous type have been a focus of attention. An example of a light emitting element of a self-luminous type is a light emitting element utilizing electroluminescence. Such a light emitting element includes a light emitting material interposed between a pair of electrodes, and light emission can be obtained from the light emitting material by applying a voltage.

Compared to a liquid crystal display, such a self-luminous light emitting element has advantages such as the fact that its pixels have high visibility and the fact that it does not need a backlight. Such a self-luminous light emitting element is considered to be suitable for application as a flat panel display element. Further, such light emitting elements have a great advantage in that they can be manufactured slim and lightweight. Furthermore, a feature of such light emitting elements is that they have a very fast response speed.

Moreover, since such self-luminous light emitting elements can be formed as films, by forming elements with a large surface area, plane emission can easily be obtained. Since this is a feature that is hard to obtain in point light sources, typified by incandescent lamps and LEDs, or in line light sources, typified by fluorescent lights, such self-luminous light emitting elements have a high utility value as surface light sources that can be applied to lighting and the like.

Light emitting elements that employ electroluminescence are differentiated by whether their light emitting material is an organic compound or an inorganic compound. Generally, light emitting elements with an organic compound as a light emitting material are called organic EL elements, and light emitting elements with an inorganic compound as a light emitting material are called inorganic EL elements.

Inorganic EL elements are classified into dispersion-type inorganic EL elements and thin-film inorganic EL elements, according to the structure of the element. These differ in that the former include a light emitting layer in which particles of a light emitting material are dispersed in a binder, and the latter include a light emitting layer formed of a thin film of light emitting material. However, they share the fact that they both require electrons accelerated by a high electric field. Note that, as a mechanism of luminescence that is obtained, there is donor-acceptor recombination light emission that utilizes a donor level and an acceptor level, and localized light emission that utilizes an inner-shell electron transition of a metal ion. Generally, in many cases, donor-acceptor recombination light emission is employed in dispersion-type inorganic EL elements, whereas localized light emission is employed in thin-film type inorganic EL elements.

Such inorganic EL elements have the advantage of having a long life compared to organic EL elements. However, since they require electrons accelerated by a high electric field in the light emitting layer, generally, it is necessary to apply a voltage of several hundreds of volts to the light emitting element. For example, in recent years, a high luminance blue light emitting inorganic EL element, which is necessary for a full-color display, has been developed. However, this blue light emitting inorganic EL element requires a drive voltage of 100 to 200 V (for example, see Reference 1: Japanese Journal of Applied Physics, 1999, Vol. 38, pp. L1291-L1292). Therefore, inorganic EL elements have large power consumption, so it has been difficult to use them as medium and small-sized displays, such as displays of portable telephones or the like.

### DISCLOSURE OF INVENTION

In view of the foregoing, an object of the present invention is to provide a novel light emitting material. Further, an object of the invention is to provide a light emitting element that is capable of low voltage drive. Still further, it is an object of the invention to provide a light emitting device and an electronic device that have reduced power consumption. Furthermore, it is an object of the invention to provide light emitting devices and electronic devices that can be manufactured at low cost.

In an aspect of the invention, a light emitting element includes a pair of electrodes, and a light emitting layer which is between the pair of electrodes. The light emitting layer includes a compound ABC₂ (where A=Cu or Ag, B═Al, Ga, or In, and C═S, Se, or Te).

In another aspect of the invention, a light emitting element includes a pair of electrodes, and a light emitting layer which is interposed between the pair of electrodes. A semiconductor layer which includes a compound ABC₂ (where A=Cu or Ag, B═Al, Ga, or In, and C═S, Se, or Te) is provided so as to be in contact with the light emitting layer.

A light emitting element has either of the above-described structures, and the light emitting layer includes a sulfide, an oxide, or a nitride.

Alternatively, a light emitting element has one of the above-described structures, and the light emitting layer includes zinc sulfide.

A light emitting element has one of the above-described structures, and the light emitting layer includes one or more elements selected from among manganese (Mn), copper (Cu), samarium (Sm), terbium (Th), erbium (Er), thulium (Tm), europium (Eu), cerium (Ce), and praseodymium (Pr).

A light emitting element has one of the above-described structures, and the light emitting layer includes one or both of fluorine (F) and chlorine (Cl).

Alternatively, a light emitting element has one of the above-described structures, and the light emitting layer includes an impurity element that forms an acceptor level.

Alternatively, a light emitting element has one of the above-described structures, and the light emitting layer includes a first impurity element that forms a donor level and a second impurity element that forms an acceptor level.

Further, the invention also includes a light emitting device that includes any one of the above-mentioned light emitting elements. A light emitting device as referred to in this specification includes an image display device, a light emission device, and a light source (including a lighting system). Furthermore, a light emitting device as referred to in this specification also includes a module in which a connector, for example an FPC (flexible printed circuit), TAB (tape automated bonding) tape, or a TCP (tape carrier package), is fitted to a panel including light emitting elements; a module that includes a panel including light emitting elements and in which a printed circuit board is provided at the end of TAB tape or a TCP; and a module in which an IC (integrated circuit) is directly mounted on a panel including light emitting elements by a COG (chip on glass) method.

Further, an electronic device that employs a light emitting element of the invention in a display portion is also included in the invention. Therefore, an electronic device of the invention includes a display portion, and the display portion is equipped with the light emitting element and with a control means that controls the light emission of the light emitting element.

A light emitting element of the invention is capable of low voltage drive.

Since a light emitting device of the invention includes a light emitting element that can be driven with a low voltage, its power consumption can be reduced. Further, since a driver circuit with a high withstand voltage is not necessary, the manufacturing cost of the light emitting device can be reduced.

### BRIEF DESCRIPTION OF DRAWINGS

FIG. 1 illustrates a light emitting element of the invention.

FIG. 2 illustrates a light emitting element of the invention.

FIG. 3 illustrates a light emitting device of the invention.

FIG. 4 illustrates a light emitting device of the invention.

FIG. 5 illustrates a light emitting device of the invention.

FIGS. 6A and 6B illustrate a light emitting device of the invention.

FIG. 7 illustrates a light emitting device of the invention.

FIGS. 8A and 8B illustrate a light emitting device of the invention.

FIGS. 9A to 9D illustrate electronic devices of the invention.

FIG. 10 illustrates a lighting system of the invention.

FIGS. 11A to 11C illustrate lighting systems of the invention.

FIG. 12 illustrates a lighting system of the invention.

FIG. 13 illustrates lighting systems of the invention.

FIG. 14 illustrates an electronic device of the invention.

FIG. 15 illustrates an electronic device of the invention.

### BEST MODE FOR CARRYING OUT THE INVENTION

### Embodiment Modes

Hereinafter, embodiment modes of the present invention will be described in detail, with reference to the accompanying drawings. However, the invention is not limited to the description below, and those skilled in the art will appreciate that a variety of modifications can be made to the embodiment modes and their details without departing from the spirit and scope of the invention. Accordingly, the invention should not be construed as being limited to the description of the embodiment modes which follows.

### Embodiment Mode 1

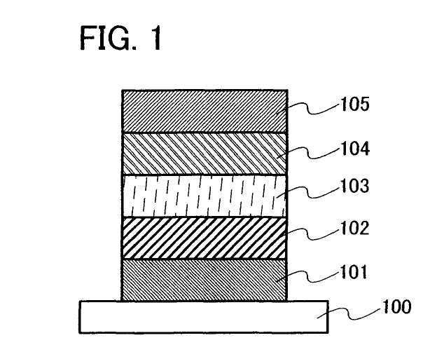

In this embodiment mode, a thin film light emitting element of the invention will be described with reference to FIG. 1.

A light emitting element described in this embodiment mode has a structure in which over a substrate 100 are formed a first electrode 101, a second electrode 105, a first insulating layer 102 which is in contact with the first electrode 101, a second insulating layer 104 which is in contact with the second electrode 105, and a light emitting layer 103 which is formed between the first insulating layer 102 and the second insulating layer 104. Light emission is obtained from the light emitting element shown in this embodiment mode when a voltage is applied between the first electrode 101 and the second electrode 105; however, operation is possible with either direct current drive or alternating current drive.

The substrate 100 is used as a support for the light emitting element. As the substrate 100, glass, plastic, or the like can be used, for example. Note that as long as the substrate serves as a support for the light emitting element in the manufacturing process, materials other than these can be used for the substrate.

Materials that form the first insulating layer 102 and the second insulating layer 104 are inorganic materials, such as an oxide. For example, barium titanate (BaTiO₃) or tantalum pentoxide (Ta₂O₅), which have a high relative permittivity, or the like, can be used.

As the first electrode 101 and the second electrode 105, metal, an alloy, a conductive compound, or a mixture of these can be used. Note that in order to obtain plane emission, it is necessary for one or both of the first electrode 101 and the second electrode 105 to have a light-transmitting property. Examples that can be given of a material for an electrode having a light-transmitting property include indium tin oxide (ITO), indium tin oxide containing silicon oxide (ITSO), indium zinc oxide (IZO), indium oxide containing tungsten oxide and zinc oxide (IWZO), and the like. A conductive metal oxide film of these materials is generally formed by sputtering. For example, IZO can be formed by sputtering using a target in which zinc oxide is added to indium oxide at 1 to 20 wt %. Further, IWZO can be formed by sputtering using a target containing 0.5 to 5 wt % tungsten oxide and 0.1 to 1 wt % zinc oxide with respect to indium oxide. Further, in the case of using a metal electrode as a light-transmitting electrode, even when a material with a low visible light transmission rate is used, by forming the electrode to a thickness of about 1 nm to 50 nm, preferably about 5 nm to 20 nm, the electrode can be used as a light transmitting electrode. As a metal electrode, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), or a nitride of a metal material, for example, titanium nitride (TiN), or the like can be used. Note that besides sputtering, vacuum evaporation, CVD, or a sol-gel method can also be used to manufacture the electrodes.

The light emitting layer 103 includes a ternary compound ABC₂ (where A=Cu or Ag, B═Al, Ga, or In, and C═S, Se, or Te) called a ‘chalcopyrite’. As such a chalcopyrite compound, for example, CuAlS₂, CuAlSe₂, CuAlTe₂, CuGaS₂, CuGaSe₂, CuGaTe₂, CuInS₂, CuInSe₂, CuInTe₂, AgAlS₂, AgAlSe₂, AgAlTe₂, AgGaS₂, AgGaSe₂, AgGaTe₂, AgInS₂, AgInSe₂, or AgInTe₂ can be used.

Note a layer including an inorganic EL base material containing the chalcopyrite compound ABC₂ may be used as the light emitting layer 103. As a base material in this case, a sulfide, an oxide or a nitride can be used. As a sulfide, for example, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used. Further, as an oxide, for example, zinc oxide (ZnO), yttrium oxide (Y₂O₃), or the like can be used. As a nitride, for example, aluminum nitride (AlN), gallium nitride (GaN), indium nitride (InN), or the like can be used. Furthermore, zinc selenide (ZnSe), zinc telluride (ZnTe), or the like can also be used as a base material. A ternary mixed crystal such as calcium sulfide-gallium (CaGa₂S₄), strontium sulfide-gallium (SrGa₂S₄), barium sulfide-gallium (BaGa₂S₄) or the like may also be used.

Further, a material with a light emission center may be included in the light emitting layer 103. As a material with a light emission center for localized light emission, for example, one or two or more elements selected from among manganese (Mn), copper (Cu), samarium (Sm), terbium (Tb), erbium (Er), thulium (Tm), europium (Eu), cerium (Ce), praseodymium (Pr), and the like can be used. Note that as charge compensation, a halogen element such as fluorine (F), chlorine (Cl), or the like may be added. Meanwhile, as a light emitting material with a donor-acceptor recombination-type light emission center, a light emitting material including a first impurity element which forms a donor level and a second impurity element which forms an acceptor level can be used. As the first impurity element, for example, fluorine (F), chlorine (Cl), aluminum (Al), or the like can be used. As the second impurity element, for example, copper (Cu), silver (Ag), or the like can be used. Note that as there are cases where a lattice defect or the like forms a donor level, the first impurity element is not always necessary.

Various methods can be used to manufacture the chalcopyrite compound ABC₂, such as a solid phase method or a liquid phase method (for example, a coprecipitation method). A liquid phase method such as a spray pyrolysis method, a double decomposition method, a method employing a pyrolytic reaction of a precursor, a reverse micelle method, a method in which one or more of the above methods is combined with high-temperature baking, or a freeze-drying method can be used.

In the solid phase method, synthesis is conducted by a solid phase reaction. Elements for forming the chalcopyrite compound or a compound containing such elements is weighed, mixed in a mortar, heated and baked in an electric furnace. The baking temperature is preferably 700 to 1500° C. This is because if the temperature is too low, below 700° C., the solid phase reaction will not progress, and if the temperature is too high, above 1500° C., the base material will decompose. Baking may be conducted with the materials in powdered form; however, it is preferable to conduct baking with the materials in pellet form. Synthesis of a light emitting material using a solid phase method requires baking at a comparatively high temperature but is simple, and thus has high productivity and is suitable for mass production.

The liquid phase method (for example, a coprecipitation method) is a method of synthesis in which elements for forming the chalcopyrite compound or a compound containing such elements is reacted in a solution, dried, then baked. In the synthesis of a light emitting material using a liquid phase method, since particles of the light-emitting material are dispersed uniformly and the particles have a small diameter, the reaction can progress even at a low baking temperature.

Below, a method for synthesizing a chalcopyrite compound using a solid phase method will be described. Firstly, a compound A₂C and a compound B₂C₃ are weighed out such that the molar ratio between them is 1:1, and mixed in a mortar. Subsequently, they are baked by being heated in an electric furnace. Baking may be conducted after the material has been heated in a sealed evacuated tube, or may be conducted while flowing a gas containing a chalcogen element. As a gas that contains a chalcogen element, hydrogen sulfide (H₂S) or the like may be used. Note that the baking temperature is preferably 700 to 1500° C., and baking is preferably conducted with the materials in pellet form, rather than in powdered form.

As the compound A₂C, copper sulfide (Cu₂S), copper selenide (Cu₂Se), copper telluride (Cu₂Te), silver sulfide (Ag₂S), silver selenide (Ag₂Se), or silver telluride (Ag₂Te) can be used. As the compound B₂C₃, aluminum sulfide (Al₂S₃), aluminum selenide (Al₂Se₃), aluminum telluride (Al₂Te₃), gallium sulfide (Ga₂S₃), gallium selenide (Ga₂Se₃), gallium telluride (Ga₂Te₃), indium sulfide (In₂S₃), indium selenide (In₂Se₃), or indium telluride (In₂Te₃) can be used.

As a method for forming the light emitting layer 103, a vacuum evaporation method such as resistive heating evaporation or electron-beam evaporation (EB evaporation), sputtering, a metalorganic CVD method, a low pressure hydride transport CVD method, an atomic layer epitaxy method (ALE), or the like can be used. There is no particular limitation on the film thickness, but preferably it is in the 10 to 1000 nm range.

Since a light emitting element formed in this manner includes a chalcopyrite compound with high electrical conductivity in a light emitting layer, it has low resistance, and thus can be driven at a low voltage.

### Embodiment Mode 2

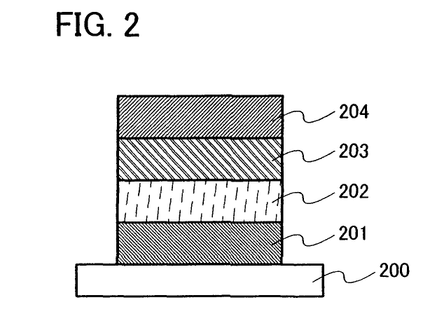

In this embodiment mode, a thin film light emitting element of the invention will be described with reference to FIG. 2.

The light emitting element described in this embodiment mode has a structure which includes a first electrode 201 and a second electrode 204 that are over a substrate 200. Interposed between the first electrode 201 and the second electrode 204 are a semiconductor layer 202 including a chalcopyrite compound, and a light emitting layer 203. In the light emitting element described in this embodiment mode, light emission is obtained by applying a voltage between the first electrode 201 and the second electrode 204; however, the light emitting element can operate using direct current drive or alternating current drive.

For the substrate 200, the first electrode 201, and the second electrode 204, the same materials as those described in Embodiment Mode 1 can be used. Further, as the semiconductor layer 202 including a chalcopyrite compound, a layer including the compound ABC₂, referred to as a ‘chalcopyrite’, which was described in Embodiment Mode 1, can be used.

The light emitting layer 203 is a thin film of light emitting material, and can be a light emitting material in which a material with a light emission center has been added to a base material.

As a base material, a sulfide, an oxide, or a nitride can be used. As a sulfide, for example, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used. Further, as an oxide, for example, zinc oxide (ZnO), yttrium oxide (Y₂O₃), or the like can be used. Moreover, as a nitride, for example, aluminum nitride (AlN), gallium nitride (GaN), indium nitride (InN), or the like can be used. Further, zinc selenide (ZnSe), zinc telluride (ZnTe), or the like can also be used. Ternary mixed crystal such as calcium gallium sulfide (CaGa₂S₄), strontium gallium sulfide (SrGa₂S₄), or barium gallium sulfide (BaGa₂S₄) may also be used.

As a material with a light emission center included in the light emitting material, for example, as a material with a light emission center for localized light emission, one or more of manganese (Mn), copper (Cu), samarium (Sm), terbium (Th), erbium (Er), thulium (Tm), europium (Eu), cerium (Ce), praseodymium (Pr), or the like can be used. Further, as charge compensation, a halogen element such as fluorine (F) or chlorine (Cl), or the like may be added. Meanwhile, a light emitting material with a donor-acceptor recombination-type light emission center is formed from a first impurity element that forms a donor level and a second impurity element that forms an acceptor level. As the first impurity element, for example, fluorine (F), chlorine (Cl), aluminum (Al), or the like can be used. As the second impurity element, for example, copper (Cu), silver (Ag), or the like can be used. Note that since there are cases where lattice defects or the like form a donor level, the first impurity element is not always necessary.

Various methods can be used to manufacture the light emitting material, such as a solid phase method or a liquid phase method (for example, a coprecipitation method). A liquid phase method such as a spray pyrolysis method, a double decomposition method, a method employing a pyrolytic reaction of a precursor, a reverse micelle method, a method in which one or more of the above methods is combined with high-temperature baking, or a freeze-drying method can be used.

In the solid phase method, synthesis is conducted by a solid phase reaction. A base material, and an element to be included in the base material or a compound containing such an element, are weighed, mixed in a mortar, then heated and baked in an electric furnace. The baking temperature is preferably 700 to 1500° C. This is because if the temperature is too low, below 700° C., the solid phase reaction will not progress, while if the temperature is too high, above 1500° C., the base material will decompose. Baking may be conducted with the materials in powdered form; however, it is preferable to conduct baking with the materials in pellet form. Synthesis of the light emitting material using the solid phase method requires baking to be conducted at a comparatively high temperature. However, this method is simple, and thus it has high productivity and is suitable for mass production.

In a liquid phase method (for example, a coprecipitation method) of synthesis, a base material or a compound containing a base material, and an element to be included in the base material or a compound containing such an element are reacted in a solution, dried, then baked. In the synthesis of a light emitting material using a liquid phase method, since particles of the light emitting material are dispersed uniformly and the particles have a small diameter, the reaction can progress even at a low baking temperature.

A method of synthesizing the light emitting material using a solid phase method will now be described. A base material, and elements that form a light emitting material with a donor-acceptor recombination-type light emission center or compounds containing such elements are each weighed, mixed in a mortar, then baked by being heated in an electric furnace. As a base material, the base materials mentioned above can be used. For the light emitting material with donor-acceptor recombination-type light emission center, as a first impurity element, for example, fluorine (F), chlorine (Cl), or the like can be used; as a compound containing a first impurity element, for example, aluminum sulfide (Al₂S₃) or the like can be used; as a second impurity element, for example, copper (Cu), silver (Ag), or the like can be used; and as a compound containing a second impurity element, for example, copper sulfide (Cu₂S), silver sulfide (Ag₂S), or the like can be used. As a baking temperature, 700 to 1500° C. is preferable. Note that baking is preferably conducted with the materials in pellet form, rather than in powdered form.

Further, in the case of employing a solid phase reaction, a compound including a first impurity element and a second impurity element may also be used. In such a case, since the impurity elements are easily diffused and the solid phase reaction proceeds readily, a uniform light emitting material can be obtained. In addition, since an unnecessary impurity element does not enter, a light emitting material with high purity can be obtained. As a compound including a first impurity element and a second impurity element, for example, copper chloride (CuCl), silver chloride (AgCl), or the like can be used.

Note that the concentration of these impurity elements in the base material may be 0.01 to 10 atomic percent, and is preferably in the range of 0.05 to 5 atomic percent.

As a method of forming the semiconductor layers 202 and 203 containing a chalcopyrite compound, a vacuum evaporation method such as resistive heating evaporation or electron-beam evaporation (EB evaporation) can be used. Further, sputtering, a metalorganic CVD method, a low pressure hydride transport CVD method, an atomic layer epitaxy method (ALE), or the like can be used. There is no particular limitation on the film thickness, but preferably it is in the 10 to 1000 nm range.

Further, buffer layers may be provided between the semiconductor layer 202 containing a chalcopyrite compound and the first electrode 201 and between the light emitting layer 203 and the second electrode 204, although they are not shown in the drawing. A buffer layer has the advantageous effect of reducing the barrier of the interface of an electrode and a semiconductor layer, and facilitating the injection of carriers from the electrode to the semiconductor layer. There is no particular limitation on the material used for a buffer layer. As a buffer layer, for example, ZnS, ZnSe, ZnTe, CdS, SrS, BaS, or the like can be used. Alternatively, CuS, Cu₂S, or LiF, CaF₂, BaF₂, MgF₂, or the like, which are alkali halides, can be used.

In a light emitting element of the invention, a semiconductor layer containing a chalcopyrite compound, which is bipolar, exhibiting both p-type and n-type conductivity, is provided between an electrode and a light emitting layer. Therefore, in a light emitting element of the invention, carriers can be efficiently transported to the light emitting layer, so a light emitting element that can operate with a low drive voltage can be obtained. Further, since light emission can be obtained with a low drive voltage, a light emitting element with reduced power consumption can be obtained.

### Embodiment Mode 3

In this embodiment mode, a light emitting device having a light emitting element manufactured applying the invention will be described.

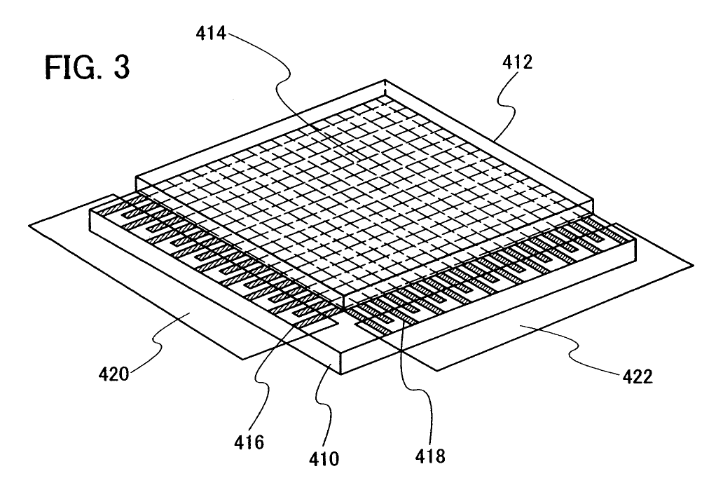

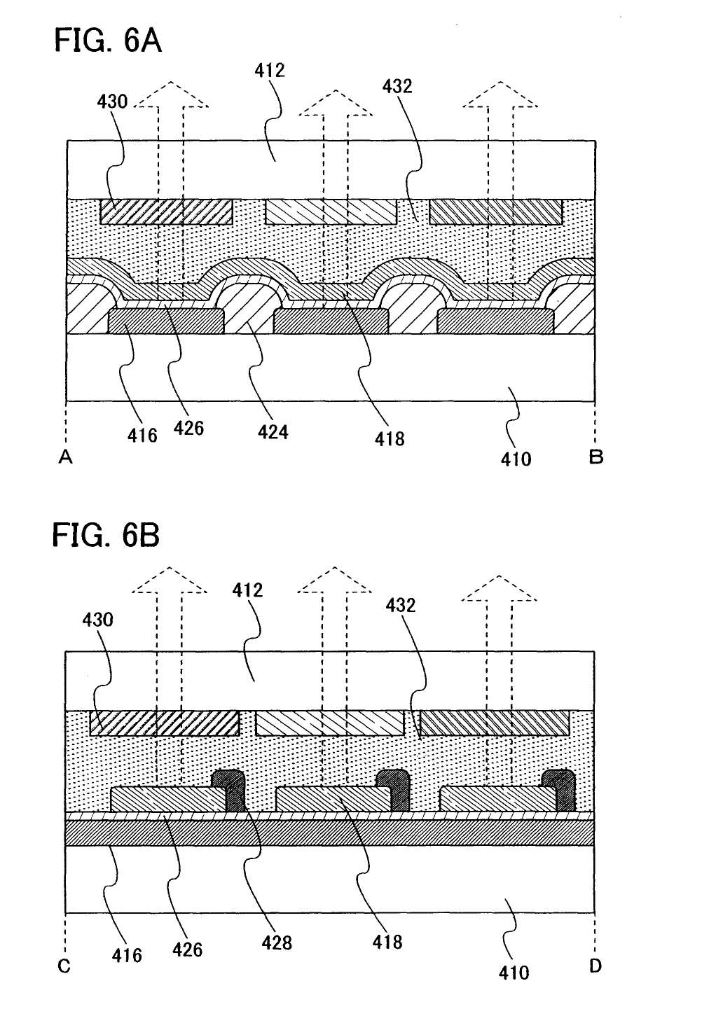

In this embodiment mode, as one mode of the light emitting device, a display device will be explained with reference to FIGS. 3 to 7. FIGS. 6A and 6B are schematic block diagrams showing a main part of the display device.

In FIG. 3, a first electrode 416 and a second electrode 418 that extends in a direction intersecting the first electrode 416 are provided over a substrate 410. A light emitting layer is provided at at least the intersection of the first electrode 416 and the second electrode 418, thereby forming a light emitting element similar to that described in Embodiment Mode 1 or Embodiment Mode 2. In the display device in FIG. 3, a plurality of first electrodes 416 and second electrodes 418 are disposed, and light emitting elements of pixels are arranged in a matrix, thereby forming a display portion 414. In the display portion 414, light emission and non-light emission of each light emitting element are controlled by controlling the potential of the first electrodes 416 and the second electrodes 418. Thereby, moving images or still images can be displayed.

In the display device shown in FIG. 3, light emission and non-light emission of a light emitting element is selected by applying a signal to display an image to each of the first electrode 416, which extends in one direction over the substrate 410, and the second electrode 418, which intersects the first electrode 416. In other words, the display device is a simple matrix display device in which drive of a pixel is mainly conducted by a signal supplied from an external circuit. A display device such as this has a simple structure, and thus can be easily manufactured even when it is formed with a large area.

A counter substrate 412 may be provided if necessary, and can serve as a protective member when provided adjusted to the position of the display portion 414. The protective member does not have to be a hard plate. A resin film or a resin material may be applied and used instead. The first electrode 416 and the second electrode 418 are led to end portions of the substrate 410, and serve as terminals that connect with external circuits. In other words, the first electrode 416 and the second electrode 418 are in contact with flexible wiring boards 420 and 422 at end portions of the substrate 410, and are connected with the external circuits through the flexible wiring boards 420 and 422. The external circuits include a power supply circuit, a tuner circuit, and the like, as well as a controller circuit that controls a video signal.

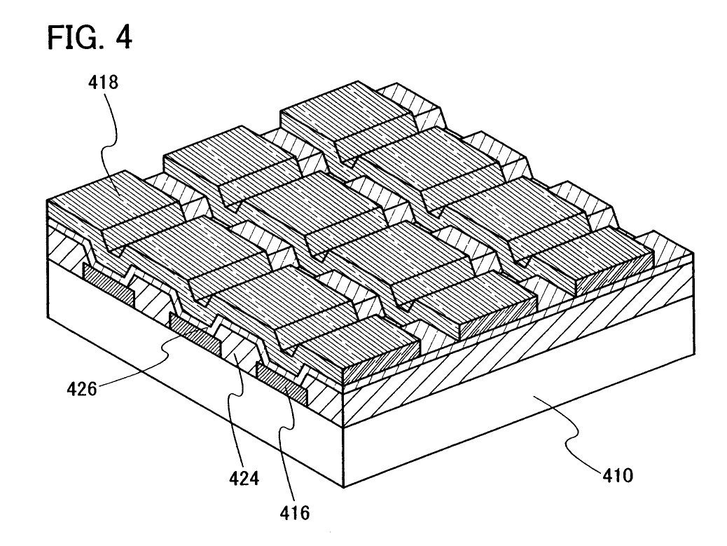

FIG. 4 is a partial enlarged view of a structure of the display portion 414 shown in FIG. 3. A partition layer 424 is formed on a side end portion of the first electrode 416, which is formed over the substrate 410. An EL layer 426 is formed at least over the first electrode 416. Here, the EL layer 426 includes a first insulating layer, a second insulating layer, and the light emitting layer described in Embodiment Mode 1 that is formed between the first insulating layer and the second insulating layer. Alternatively, the EL layer 426 may have the structure described in Embodiment Mode 2, in which a light emitting layer is provided over a semiconductor layer. The second electrode 418 is formed over the EL layer 426. The second electrode 418 is formed over the partition layer 424 such that it intersects with the first electrode 416. The partition layer 424 is formed using an insulating material, so as to prevent short-circuiting between the first electrode 416 and the second electrode 418. In a portion where the partition layer 424 covers an end portion of the first electrode 416, a side end portion of the partition layer 424 is sloped so that it does not form a steep step, such that it has a so-called tapered shape. In the case where the partition layer 424 has such a shape, coverage of the EL layer 426 and the second electrode 418 improves, and defects such as cracks or tears can be prevented.

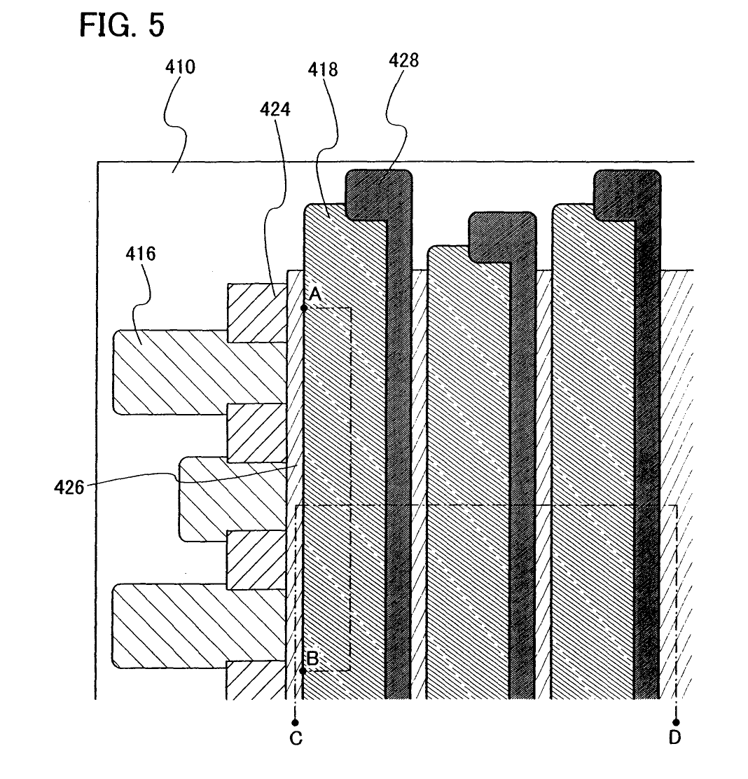

FIG. 5 is a plane view of the display portion 414 shown in FIG. 3, showing the arrangement of the first electrode 416, the second electrode 418, the partition layer 424, and the EL layer 426. In the case where the second electrode 418 is formed of a conductive film of an oxide having a light transmitting property, such as indium tin oxide or zinc oxide, an auxiliary electrode 428 is preferably provided so as to reduce the resistance loss. In this case, the auxiliary electrode 428 may be formed using a refractory metal such as titanium, tungsten, chromium, or tantalum, or a combination of the refractory metal and a low resistance metal such as aluminum or silver.

FIGS. 6A and 6B show cross-sectional views taken along the line A-B and the line C-D, respectively, in FIG. 5. A light emitting element, in which the EL layer 426 is formed, is formed at an intersection of the first electrode 416 and the second electrode 418. The auxiliary electrode 428 shown in FIG. 6B is provided over the partition layer 424 and is provided so as to be in contact with the second electrode 418. Since the auxiliary electrode 428 is provided over the partition layer 424, light from the light emitting element formed at the intersection of the first electrode 416 and the second electrode 418 is not blocked, so the emitted light can be efficiently utilized. In addition, with this structure, short-circuiting between the auxiliary electrode 428 and the first electrode 416 can be prevented.

In FIGS. 6A and 6B, examples in which color conversion layers 430 are disposed on the counter substrate 412 are shown. The color conversion layer 430 converts the wavelength of light emitted from the EL layer 426 so that the color of the light emission is changed. In this case, light emitted from the EL layer 426 is preferably blue light or ultraviolet light with high energy. When color conversion layers 430 for converting light to red, green, and blue light are each disposed, a display device that performs RGB full-color display can be obtained. Furthermore, a color conversion layer 430 can be replaced by a colored layer (a color filter). In that case, the EL layer 426 may be formed so as to emit white light. A filler 432 may be provided as appropriate, to fix the substrate 410 and the counter substrate 412 to each other.

In the above description, in a case where the first electrode 416 is formed using aluminum, titanium, tantalum, or the like, and the second electrode 418 is formed using a light-transmitting material, such as indium oxide, indium tin oxide (ITO), indium tin oxide containing silicon oxide, indium zinc oxide, zinc oxide, or indium oxide containing tungsten oxide and zinc oxide (IWZO), a display device having the display portion 414 on the counter substrate 412 side can be obtained. In this case, if a thin oxide film is formed over a surface of the first electrode 416, a barrier layer is formed and luminous efficiency can be improved due to a carrier blocking effect. In a case where the first electrode 416 is formed using a light-transmitting material, such as indium oxide, indium tin oxide (ITO), indium tin oxide containing silicon oxide, indium zinc oxide, zinc oxide, or indium oxide containing tungsten oxide and zinc oxide (IWZO), and the second electrode 418 is formed using aluminum, titanium, tantalum or the like, a display device having the display portion 414 on the substrate 410 side can be obtained. Furthermore, in the case where both the first electrode 416 and the second electrode 418 are formed as electrodes having a light-transmitting property, a display device capable of display on both sides can be obtained.

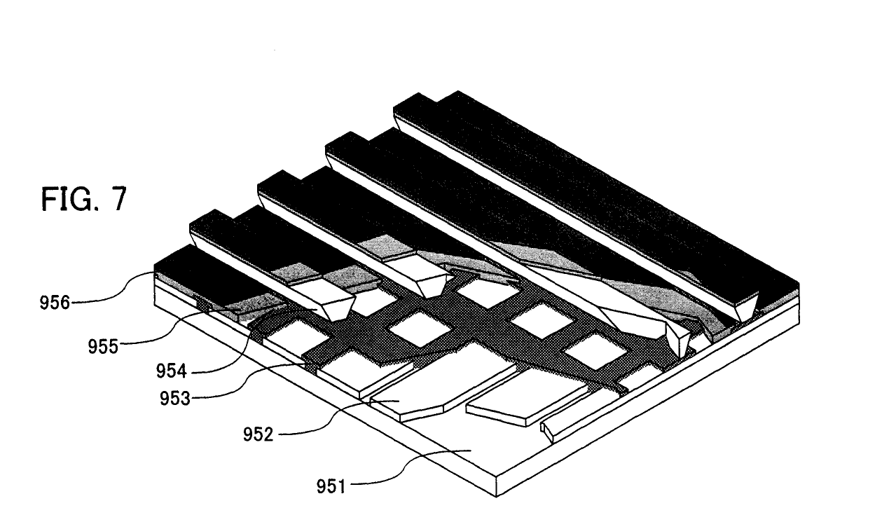

Another structure of the display portion 414 is shown in FIG. 7. In the structure shown in FIG. 7, a side end portion of a first electrode 952 is covered by an insulating layer 953. In addition, a partition layer 954 is provided over the insulating layer 953. Sidewalls of the partition layer 954 have a slant such that the distance between one sidewall and the other sidewall of the partition layer 954 becomes narrower as the sidewalls get closer to the substrate 951 surface. That is, a cross-section taken along the direction of a shorter side of the partition layer 954 has a trapezoidal shape, and the base of the trapezoid (a side of the trapezoid that is parallel to the surface of the insulating layer 953 and is in contact with the insulating layer 953) is shorter than the upper side of the trapezoid (a side of the trapezoid that is parallel to the surface of the insulating layer 953 and is not in contact with the insulating layer 953). By providing the partition layer 954 in this manner, an EL layer 955 and a second electrode 956 can be formed in a self-aligning manner utilizing the partition layer 954.

Since the light emitting element in the display device of this embodiment mode emits light using a low voltage, a booster circuit or the like is not required. Therefore, the structure of the device can be simplified.

Note that this embodiment mode can be combined with other embodiment modes as appropriate.

### Embodiment Mode 4

In this embodiment mode, a light emitting device including a light emitting element manufactured by applying the invention will be described.

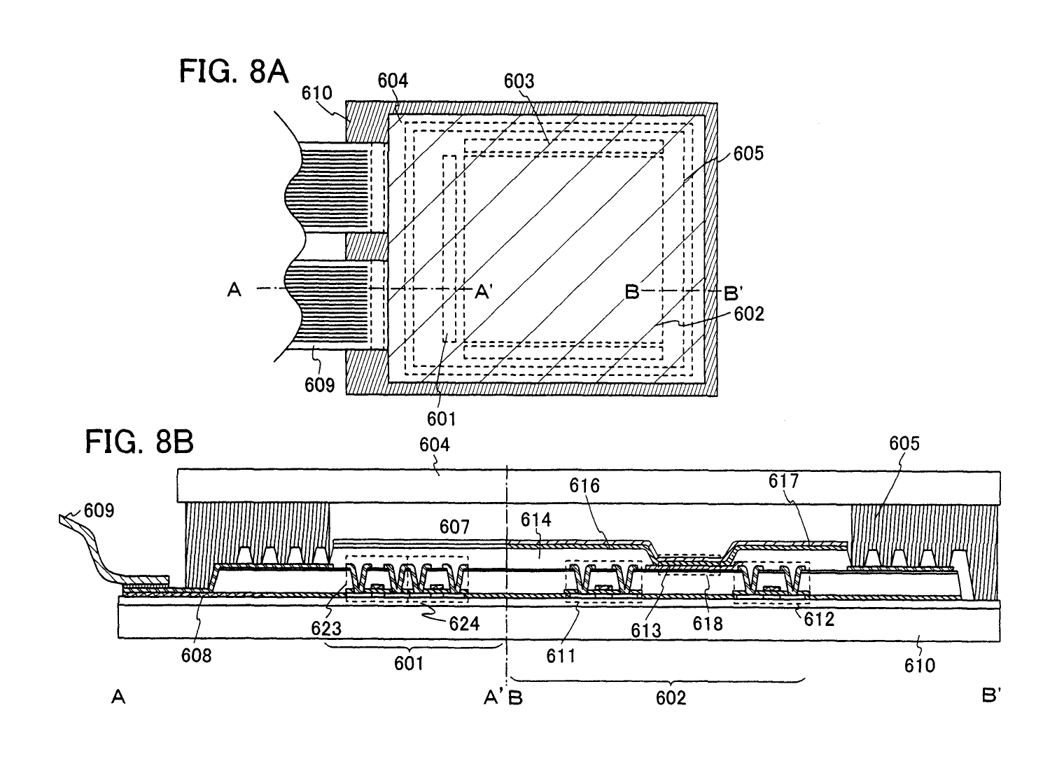

In this embodiment mode, an active light emitting device in which the drive of a light emitting element is controlled by a transistor will be described. In this embodiment mode, a light emitting device including the light emitting element manufactured by applying the invention in a pixel portion will be described with reference to FIGS. 8A and 8B. FIG. 8A is a top view of the light emitting device, and FIG. 8B is cross-sectional views of FIG. 8A taken along lines A-A′ and B-B′. In FIGS. 8A and 8B, concerning the reference numerals for the areas shown by dotted lines, 601 denotes a source side driver circuit, 602 denotes the pixel portion, and 603 denotes a gate side driver circuit. Further, reference numeral 604 denotes a sealing substrate, reference numeral 605 denotes a sealant, and an area enclosed by the sealant 605 is a space 607.

Further, a wire 608 for leading in FIG. 8B transmits signals input to the source side driver circuit 601 and the gate side driver circuit 603, and receives video signals, clock signals, start signals, reset signals, and the like from an FPC (flexible printed circuit) 609 which is an external input terminal. Note that a printed wiring board (PWB) may be attached to the FPC, although only the FPC is shown in the drawings. In this specification, ‘light emitting device’ refers not only to the body of a light emitting device, but also to the body of a light emitting device fitted with an FPC or a PWB.

Next, a cross-sectional structure will be described with reference to FIG. 8B. Over an element substrate 610, driver circuit portions and a pixel portion are formed. Here, the source side driver circuit 601, which is a driver circuit portion, and one pixel in the pixel portion 602 are shown.

Note that a CMOS circuit in which an n-channel TFT 623 and a p-channel TFT 624 are combined is formed as the source side driver circuit 601. The driver circuit may be a known CMOS circuit, a PMOS circuit, or an NMOS circuit. Furthermore, in this embodiment mode, a driver-integrated type structure in which the driver circuit is formed over the substrate is described, but a driver-integrated type structure is not necessarily required. A driver circuit can be formed external to the substrate, rather than over the substrate. Note that there is no particular restriction on the structure of the TFT. A staggered TFT or an inverse staggered TFT may be used, for example. Further, there is no particular restriction on the crystallinity of a semiconductor film used in the TFT. An amorphous semiconductor film may be used, and a crystalline semiconductor film may also be used. Moreover, there is no particular restriction on a semiconductor material used. An inorganic compound may be used, and an organic compound may also be used.

Further, the pixel portion 602 includes a plurality of pixels, which include a switching TFT 611, a current controlling TFT 612, and a first electrode 613 which is electrically connected to a drain of the current controlling TFT 612. Note that an insulating film 614 is formed so as to cover an end portion of the first electrode 613. Here, the insulating film 614 is formed using a positive photosensitive acrylic resin film.

Further, to make coatability good, either an upper end portion or a lower end portion of the insulating film 614 is formed such that it has a curved surface having a curvature. For example, in the case of using a positive photosensitive acrylic as a material for the insulating film 614, it is preferable to give only the upper end portion of the insulating film 614 a curved surface, having a curvature radius (of 0.2 to 3 μm). Further, as the insulating film 614, either a negative material, which becomes insoluble in etchant when irradiated with light, or a positive material, which becomes soluble in etchant when irradiated with light, can be used.

Over the first electrode 613, an EL layer 616 and a second electrode 617 are formed. Here, the EL layer 616 includes a first insulating layer, a second insulating layer, and the light emitting layer described in Embodiment Mode 1, which is formed between the first insulating layer and the second insulating layer. Alternatively, the EL layer 616 may have the structure described in Embodiment Mode 2, in which the light emitting layer is provided over a semiconductor layer. At least one of the first electrode 613 and the second electrode 617 has a light-transmitting property, so light emitted from the EL layer 616 can pass through the electrode to the outside.

Note that various methods can be used to form the first electrode 613, the EL layer 616, and the second electrode 617. Specifically, a vacuum evaporation method such as a resistive heating evaporation method or an electron-beam evaporation (EB evaporation) method; a physical vapor deposition (PVD) method such as sputtering; a chemical vapor deposition (CVD) method such as a metalorganic CVD method or a low pressure hydride transport CVD method; an atomic layer epitaxy method (ALE); or the like can be used. Further, an ink-jet method, a spin-coating method, or the like can be used. Moreover, different film formation methods may be used to form each electrode and to form each layer.

Furthermore, by affixing the sealing substrate 604 to the element substrate 610 with the sealant 605, a structure is obtained in which a light emitting element 618 is provided in the space 607 which is surrounded by the element substrate 610, the sealing substrate 604, and the sealant 605. Note that the space 607 is filled with a filler. The space 607 may be filled with an inert gas (such as nitrogen or argon), or with the sealant 605, for example.

Note that an epoxy-based resin is preferably used as the sealant 605. Further, it is desirable that materials used for the sealant and the filler are materials which allow as little water and oxygen as possible to penetrate. Further, as a material used for the sealing substrate 604, besides a glass substrate or a quartz substrate, a plastic substrate formed of FRP (fiberglass-reinforced plastic), PVF (polyvinyl fluoride), Mylar, polyester, acrylic, or the like can be used.

In the above manner, a light emitting device having a light emitting element manufactured applying the invention can be obtained.

The light emitting device described in this embodiment mode includes the light emitting element described in Embodiment Mode 1 or 2, and thus can operate with a low drive voltage. Therefore, a light emitting device with reduced power consumption can be obtained.

Further, since the light emitting device described in this embodiment mode does not require a driver circuit with a high withstand voltage, the manufacturing cost of the light emitting device can be reduced. Moreover, the weight of the light emitting device can be reduced, and a driver circuit portion can be made smaller.

### Embodiment Mode 5

In this embodiment mode, an electronic device which includes the light emitting device described in Embodiment Mode 3 or 4 will be described. The electronic device described in this embodiment mode includes the light emitting element described in Embodiment Mode 1 or 2. Therefore, an electronic device with reduced power consumption can be provided, since the electronic device includes a light emitting element with reduced drive voltage.

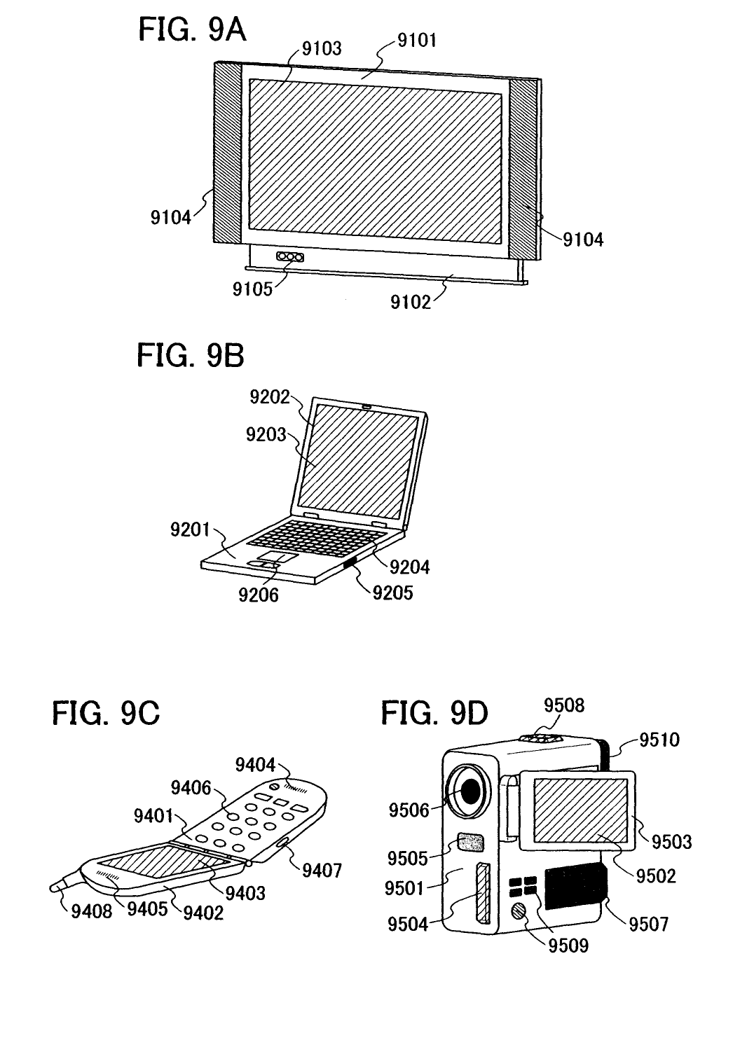

As examples of electronic devices manufactured applying the invention, a camera such as a video camera or a digital camera, a goggle-type display, a navigation system, a sound reproduction device (such as a car audio system or an audio component), a computer, a game machine, a portable information terminal (such as a mobile computer, a portable telephone, a portable game machine, or an electronic book), an image reproduction device equipped with a recording medium (specifically, a device for reproducing a recording medium such as a digital versatile disc (DVD) and having a display for displaying the image), and the like can be given. Some specific examples of such electronic devices are shown in FIGS. 9A to 9D.

FIG. 9A shows a television device of this embodiment mode that includes a housing 9101, a support 9102, a display portion 9103, speaker portions 9104, a video input terminal 9105, and the like. The display portion 9103 of the television device includes light emitting elements similar to those described in Embodiment Modes 1 or 2, that are arranged in a matrix. The light emitting elements have the features of high luminous efficiency and low drive voltage. Further, the light emitting elements can prevent short circuits which occur due to external impact or the like. The display portion 9103 which includes the light emitting elements of the invention also has these features. Accordingly, the television device has reduced deterioration of image quality and consumes less power. Thanks to these features, deterioration compensation functions and power supply circuits in the television device employing light emitting elements of the invention can be considerably cut back or reduced in size. Therefore, the housing 9101 and the support 9102 can be made smaller and lighter. The television device of this embodiment mode has low power consumption, high image quality, and reduced size and weight. Therefore, a product which is suited to a living environment can be provided.

FIG. 9B shows a computer of this embodiment mode that includes a main body 9201, a housing 9202, a display portion 9203, a keyboard 9204, an external connection port 9205, a touchpad 9206, and the like. The display portion 9203 of the computer includes light emitting elements similar to those described in Embodiment Modes 1 or 2, that are arranged in a matrix. The light emitting elements have the features of high luminous efficiency and low driving voltage. Further, they can prevent short circuits which occur due to external impact or the like. The display portion 9203 which includes the light emitting elements of the invention also has these features. Accordingly, the computer has less deterioration of image quality and consumes less power. Thanks to these features, deterioration compensation functions and power supply circuits in the computer employing light emitting elements of the invention can be considerably cut back or reduced in size. Therefore, the main body 9201 and the housing 9202 can be made smaller and lighter. The computer of this embodiment mode has low power consumption, high image quality, and reduced size and weight, so a product which is suited to an environment can be provided. Further, the computer of this embodiment mode is portable, and has a display portion which can well withstand external impacts that occur when the computer is being carried.

FIG. 9C shows a portable telephone of this embodiment mode that includes a main body 9401, a housing 9402, a display portion 9403, an audio input portion 9404, an audio output portion 9405, operation keys 9406, an external connection port 9407, an antenna 9408, and the like. The display portion 9403 of the portable telephone includes light emitting elements similar to those described in Embodiment Modes 1 or 2, that are arranged in a matrix. The light emitting elements have the features of high luminous efficiency and low driving voltage. Further, they can prevent short circuits which occur due to external impact or the like. The display portion 9403 which includes the light emitting elements of the invention also has these features. Accordingly, the portable telephone has less deterioration of image quality and consumes less power. Thanks to these features, deterioration compensation functions and power supply circuits in the portable telephone employing light emitting elements of the invention can be considerably cut back or reduced in size. Therefore, the main body 9401 and the housing 9402 can be made smaller and lighter. The portable telephone of this embodiment mode has low power consumption, high image quality, and reduced size and weight, so a product which is suited to being carried can be provided. Further, a product having a display portion which can well withstand external impacts that occur when the product is being carried can be provided.

FIG. 9D shows a camera that includes a main body 9501, a display portion 9502, a housing 9503, an external connection port 9504, a remote control receiver portion 9505, an image receiving portion 9506, a battery 9507, an audio input portion 9508, operation keys 9509, an eyepiece portion 9510, and the like. The display portion 9502 of the camera includes light emitting elements similar to those described in Embodiment Modes 1 or 2, that are arranged in a matrix. The light emitting elements have the features of high luminous efficiency and low driving voltage. Further, they can prevent short circuits which occur due to external impact or the like. The display portion 9502 which includes the light emitting elements of the invention also has these features. Accordingly, the camera has less deterioration of image quality and consumes less power. Thanks to such features, deterioration compensation functions and power supply circuits in the camera employing light emitting elements of the invention can be considerably cut back or reduced in size. Therefore, the main body 9501 can be made smaller and lighter. The camera of this embodiment mode has low power consumption, high image quality, and reduced size and weight, so a product which is suited to being carried can be provided. Further, a product having a display portion which can well withstand external impacts that occur when the product is being carried can be provided.

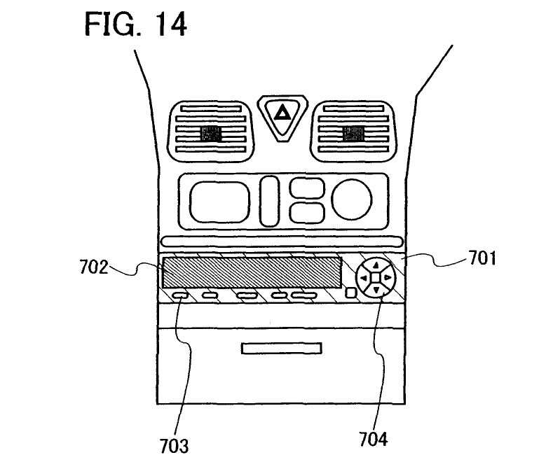

FIG. 14 shows a sound reproduction device, specifically a car audio system. The sound reproduction device includes a main body 701, a display portion 702, and operation switches 703 and 704. The display portion 702 can be formed using the light-emitting device (a passive type) described in Embodiment Mode 3 or the light-emitting device (an active type) described in Embodiment Mode 4. Further, the display portion 702 may be formed using a segment type light emitting device. In any case, by using a light-emitting material of the present invention, a display portion can be formed that uses a vehicular power source (12 to 42 V) and therefore has lower power consumption, yet is bright. The display portion also has a longer life, due to having lower power consumption. Further, although this embodiment mode has described an in-car audio system, a light emitting element of the present invention may also be used in a portable audio system or an audio system for home use.

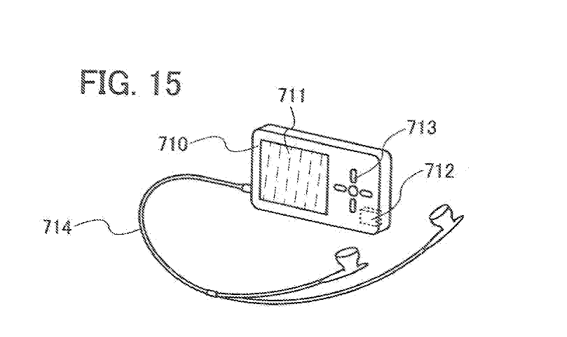

FIG. 15 shows a portable digital player as an example of using a light element of the present invention in an audio system other than an in-car audio system. The digital player shown in FIG. 15 includes a main body 710, a display portion 711, a memory portion 712, an operation portion 713, a pair of earphones 714, and the like. Note that a pair of headphones or a wireless pair of earphones can be used instead of the pair of earphones 714. The display portion 711 can be formed using the light-emitting device (a passive type) shown in Embodiment Mode 3 or the light-emitting device (an active type) shown in Embodiment Mode 4. Further, the display portion 711 may be formed using a segment type light emitting device. In any case, by using a light-emitting material of the present invention, a display portion can be formed that is capable of bright display even when using a secondary battery (a nickel-hydrogen battery or the like). The display portion also has a longer life and low power consumption. As the memory portion 712, a hard disk or a nonvolatile memory is used. For example, a NAND-type nonvolatile memory with a recording capacity of 20 to 200 gigabytes (GB) is used, and by operating the operation portion 713, an image or a sound (e.g., music) can be recorded and reproduced. In the display portions 702 and 711 of FIGS. 14 and 15, respectively, white characters are displayed against a black background. Thus, power consumption can be reduced. This is particularly effective for portable audio systems.

As described above, the range of application of a light emitting device manufactured applying the invention is extremely wide. The light emitting device can be applied to electronic devices in all kinds of fields. By applying the invention, an electronic device including a display portion that consumes less power and has high reliability can be manufactured.

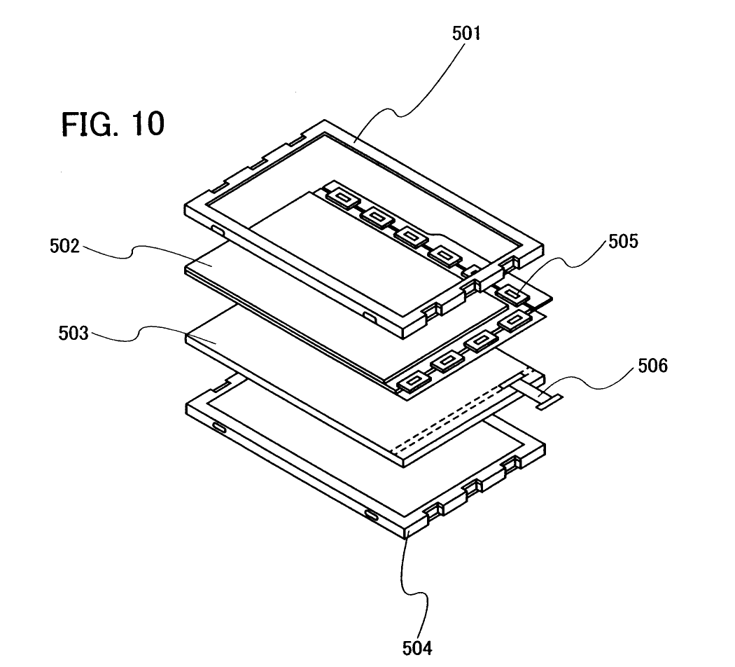

Further, a light emitting device to which the invention is applied includes a light emitting element with high luminous efficiency, and can also be used as a lighting system. One mode of using a light emitting element to which the present invention is applied as a lighting system will be described with reference to FIG. 10.

FIG. 10 shows an example of a liquid crystal display device that uses a light emitting device to which the present invention is applied as a backlight. The liquid crystal display device shown in FIG. 10 includes a housing 501, a liquid crystal layer 502, a backlight 503, and a housing 504. The liquid crystal layer 502 is connected to a driver IC 505. Further, a light-emitting device of the present invention is used as the backlight 503, to which a voltage is supplied through a terminal 506.

By using a light emitting device of the present invention as a backlight of a liquid crystal display device, a backlight with high luminance and long life can be obtained. Thus, the quality of the display device is improved. Further, since a light emitting device of the invention is a plane emission light-emitting device and can have a large surface area, the backlight can have a large surface area, so the liquid crystal display device can also have a large surface area. Further, since the light emitting element is slim and has low power consumption, the display device can be made slimmer and can have reduced power consumption.

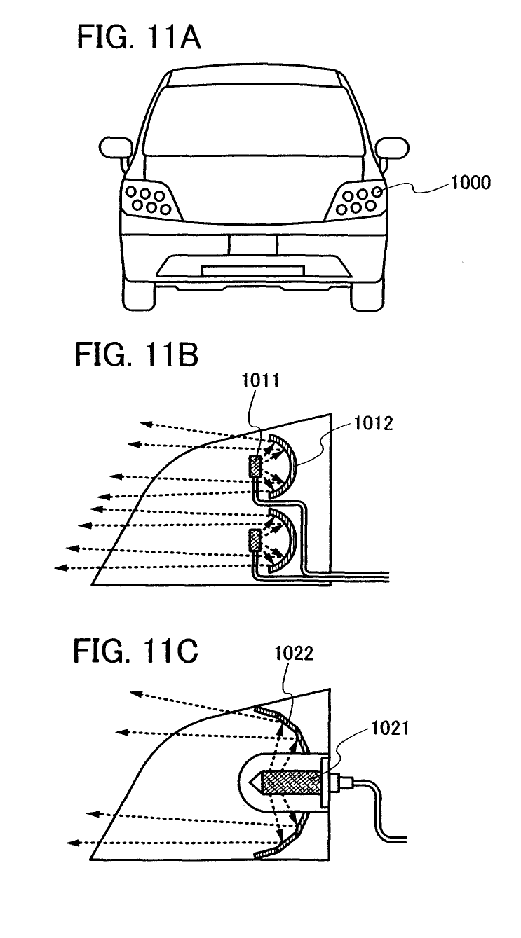

Furthermore, since a light emitting device to which the invention is applied can emit light with high luminance, it can be used as a headlight of a car, a bicycle, a ship, or the like. FIGS. 11A to 11C show an example in which a light emitting device to which the present invention is applied is used as a headlight of a car. FIG. 11B is an enlarged cross-sectional view of a headlight 1000 shown in FIG. 11A. In FIG. 11B, a light emitting device of the invention is used as a light source 1011. Light emitted from the light source 1011 is reflected by a reflector 1012 and passes to the outside. As shown in FIG. 11B, light with higher luminance can be obtained by using a plurality of light sources. FIG. 11C is an example in which a light emitting device of the invention that is manufactured in a cylindrical shape is used as a light source. Light emitted from the light source 1021 is reflected by a reflector 1022 and passes to the outside.

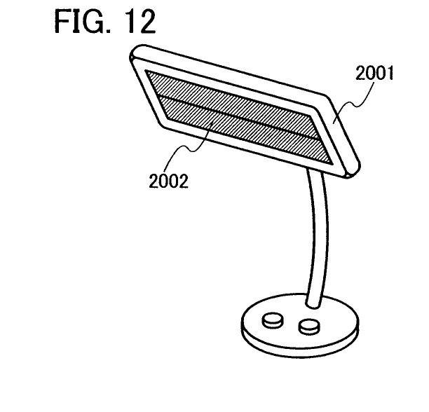

FIG. 12 shows an example in which a light-emitting device to which the present invention is applied is used as a desk lamp, which is a lighting system. The desk lamp shown in FIG. 12 includes a housing 2001 and a light source 2002. A light emitting device of the invention is used as the light source 2002. Since the light-emitting device of the present invention can emit light with high luminance, it can brightly illuminate hands in a case such as where fine handwork is being done.

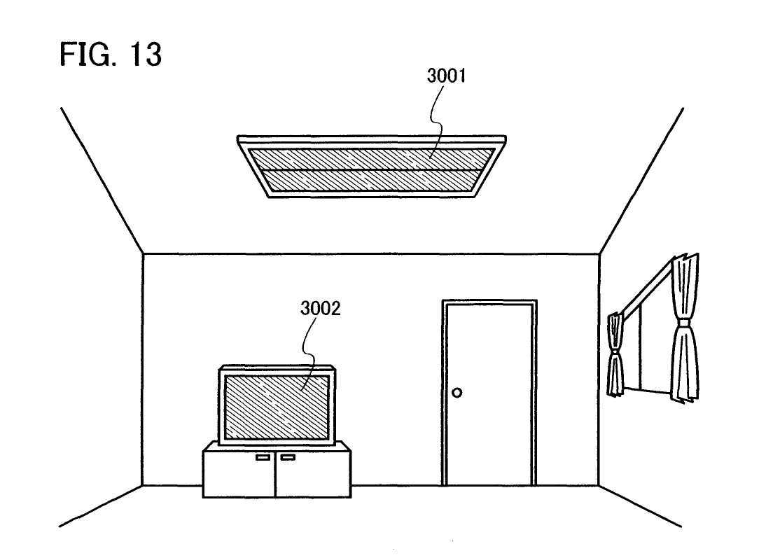

FIG. 13 shows an example in which a light emitting device to which the invention is applied is used as an interior lighting system 3001. Since the light emitting device of the invention can have a large area, it can be used as a large-area lighting system. In addition, since the light emitting device of the invention is slim and consumes less power, it can be used as a slim lighting system with less power consumption. A television device 3002 of the invention such as that shown in FIG. 9A may be placed in a room where a light emitting device to which the invention is applied is used as the interior lighting system 3001, and public broadcasting or movies can be watched there.

Lighting systems to which a light emitting device of the invention can be applied are not limited to those illustrated in FIGS. 11A to 11C, 12, and 13. The light emitting device of the invention can be applied to various modes of lighting systems, including lighting for houses and for public facilities. In such cases, since the light emitting medium of the lighting system of the invention is a thin film, design freedom is increased. Accordingly, various elaborately designed products can be provided to the marketplace.

### EXAMPLE 1

In this example, a light emitting material used in a light emitting element of the invention will be described.

Cu₂S and Ga₂S₃ were weighed out such that the molar ratio between them was 1:1, then stirred and mixed using an agate mortar. Next, CuGaS₂ was synthesized by putting that mixture into an alumina crucible and baking it for four hours at 1000° C. using an electric furnace placed under an N₂ atmosphere. The obtained light emitting material was a dark brown color. When the light emitting material was excited by light with a wavelength of 254 nm, blue light emission was observed.

### EXAMPLE 2

In this example, a light emitting material used in a light emitting element of the invention will be described.

ZnS, used here as a base material, and the CuGaS₂ obtained in Example 1 were weighed out such that the molar ratio between them was 1:1, then stirred and mixed using an agate mortar. Next, that mixture was placed into an alumina crucible and baked for four hours at 1000° C. using an electric furnace placed under an N₂ atmosphere. The obtained light emitting material was a dark brown color. When the light emitting material was excited by light with a wavelength of 254 nm, blue light emission was observed.

The present application is based on Japanese Priority application No. 2006-058580 filed on Mar. 3, 2006 with the Japanese Patent Office, the entire contents of which are hereby incorporated by reference.

1. A light emitting device comprising:
a pair of electrodes; and
a light emitting layer interposed between the pair of electrodes,
wherein the light emitting layer includes a compound ABC₂,
wherein A is Cu or Ag, B is Al, Ga, or In, and C is S, Se, or Te.

2. A light emitting device comprising:
a pair of electrodes;
a light emitting layer interposed between the pair of electrodes; and
a semiconductor layer in contact with the light emitting layer,
wherein the semiconductor layer includes a compound ABC₂,
wherein A is Cu or Ag, B is Al, Ga, or In, and C is S, Se, or Te.

3. A light emitting device comprising:
a pair of electrodes; and
a light emitting layer interposed between the pair of electrodes,
wherein the light emitting layer includes a ternary compound,
wherein the the ternary compound comprises one of Cu and Ag, and any one of Al, Ga and In, and any one of S, Se, and Te.

4. A light emitting device comprising:
a pair of electrodes;
a light emitting layer interposed between the pair of electrodes; and
a semiconductor layer in contact with the light emitting layer,
wherein the semiconductor layer includes a ternary compound,
wherein the the ternary compound comprises one of Cu and Ag, and any one of Al, Ga and In, and any one of S, Se, and Te.

5. The light emitting device according to any one of claims 1 to 4, wherein the light emitting layer includes a sulfide, an oxide, or a nitride.

6. The light emitting device according to any one of claims 1 to 4, wherein the light emitting layer includes zinc sulfide.

7. The light emitting device according to any one of claims 1 to 4, wherein the light emitting layer includes one or more elements selected from among manganese (Mn), copper (Cu), samarium (Sm), terbium (Th), erbium (Er), thulium (Tm), europium (Eu), cerium (Ce), and praseodymium (Pr).

8. The light emitting device according to any one of claims 1 to 4, wherein the light emitting layer includes one or both of fluorine (F) and chlorine (Cl).

9. The light emitting device according to any one of claims 1 to 4, wherein the light emitting layer includes an impurity element that forms an acceptor level.

10. The light emitting device according to any one of claims 1 to 4, wherein the light emitting layer includes a first impurity element that forms a donor level and a second impurity element that forms an acceptor level.

11. The light emitting device according to any one of claims 1 to 4, further comprising a control circuit for controlling light emission of the light emitting layer.

12. An electronic device comprising a display device, the display device including the light emitting device according to any one of claims 1 to 4, and a control circuit for controlling light emission of the light emitting layer.
